(19) United States
(12) Patent Application Publication
(10) Pub. No.: US 2023/0290912 A1
(43) Pub. Date: Sep. 14, 2023

(54) LED PACKAGE DEVICE AND PACKAGING METHOD

(71) Applicant: ShenZhen YunMiXin Display Technology Co., Ltd, Shenzhen (CN)

(72) Inventors: Chong Xiong, Shenzhen (CN); Chang’ao Liu, Shenzhen (CN)

(21) Appl. No.: 18/319,480

(22) Filed: May 18, 2023

(30) Foreign Application Priority Data
Jul. 8, 2022 (CN) 202210808395.2

(51) Int. Cl. H01L 33/50; H01L 33/54

(52) U.S. Cl. CPC H01L 33/507; H01L 33/54; H01L 2933/0041; H01L 2933/005

(57) ABSTRACT

An LED package device includes a substrate, an LED chip arranged on the substrate and a transparent groove. A quantum dot layer is provided inside the transparent groove, a barrier film layer is provided on the quantum dot layer, side walls of the barrier film layer are connected and sealed with side walls of the transparent groove, and a phosphor layer is provided on the barrier film layer. The transparent groove is inverted on the sealing adhesive layer and connected with the sealing adhesive layer, and an opening of the transparent groove is sealed by the sealing adhesive layer to cover the quantum dot layer, the barrier film layer and the phosphor layer. The device can isolate water vapor and oxygen, thereby effectively avoiding the failure problem of the quantum dot layer and reducing the failure risk caused by strong blue light to the quantum dot material.

### FIELD OF THE INVENTION

The present application relates to the technical field of liquid crystal display, in particular to an LED package device and a packaging method thereof.

### BACKGROUND OF THE INVENTION

Existing liquid crystal display (LCD) requires a backlight system to provide uniform area source. In order to improve the display color gamut of the LCD, it is usually to minimize the full width at half maximum (FWHM) of the green light and red light in the backlight. Quantum dot (QD) luminous material may meet the demand for color gamut in the LCD system, but has the following shortcomings. The quantum dot material may be ineffective or even failed, due to oxygen, water vapor or high energy density of excited light source (blue light usually). Based on the shortcomings of the above quantum dot material, quantum dot film as a product form of quantum dot is mainly applied in the conventional LCD backlight system. As shown in FIG. 1, a quantum dot film 10a is a product in a “sandwich” structure. The quantum dot material layer 1a is sandwiched by an upper barrier film 2a and a lower barrier film 2a which are made of PET substrates. The barrier films 2a are configured to prevent water vapor and oxygen from entering the quantum dot material layer, from the upper and lower surfaces. The quantum dot material layer 1a packaged as the “sandwich” structure is placed into the LED device to form a QD-LED package device 20a, as illustrated in FIG. 2. The LED chip 4a is installed on the substrate 3a, and the LED chip 4a is encapsulated through the sealing adhesive layer 5a, then the quantum dot film 10a is installed on the sealing adhesive layer, and the side wall of the quantum dot film 10a on the sealing adhesive layer 5a is encapsulated by the retaining wall 6a. However, since the retaining wall 6a and the quantum dot film 10a is not sealed, it's still possible for water vapor and oxygen to enter from the connection between the retaining wall 6a and the quantum dot film 10a, as shown by arrows A and B. That is to say, the quantum dot material layer 1a may still have failure sides, as shown in FIG. 3, from which the water vapor and oxygen may enter the quantum dot film 10a. Usually, such failure sides C may have a size of about 1 mm, while the size of general LED devices is 1-2 mm. By this token, such a QD-LED package device 20a has a short service life, which is not suitable for the use of liquid crystal display. Additionally, the quantum dot material layer 1a is directly contacted with the blue LED chip 4a in a close distance, and directly receives the blue light emitted by blue LED chip 4a, which leads to uneven luminescence of the blue LED chip 4a, and accordingly leads to failure of the quantum dot material due to partial high energy density.

### SUMMARY OF THE INVENTION

The present invention aims to provide an LED package device and a packaging method thereof, which can isolate water vapor and oxygen from the quantum dot layer, thereby effectively avoiding the failure problem of the quantum dot layer and reducing the failure risk caused by strong blue light to the quantum dot material.

To achieve the above purpose, as a first aspect, an LED package device of the present invention includes a substrate, an LED chip arranged on the substrate and a transparent groove. The substrate is provided with a sealing adhesive layer for cladding the LED chip. A quantum dot layer is provided inside the transparent groove, a barrier film layer is provided on the quantum dot layer, side walls of the barrier film layer are connected and sealed with side walls of the transparent groove, and a phosphor layer is further provided on the barrier film layer. The transparent groove is inverted on the sealing adhesive layer and connected with the sealing adhesive layer, and an opening of the transparent groove is sealed by the sealing adhesive layer to cover the quantum dot layer, the barrier film layer and the phosphor layer.

Preferably, one side of the phosphor layer is connected with the barrier film layer, and another side of the phosphor layer is connected with the sealing adhesive layer.

As a second aspect, a packaging method of an LED package device according to the present invention includes providing a substrate on which an LED chip is provided; providing a transparent groove, wherein a quantum dot layer is provided inside the transparent groove, a barrier film layer is provided on the quantum dot layer, side walls of the barrier film layer are connected and sealed with side walls of the transparent groove, and a phosphor layer is further provided on the barrier film layer; coating the substrate with sealing adhesive for cladding the LED chip; and inverting the transparent groove on the sealing adhesive, solidifying the sealing adhesive to form a sealing adhesive layer connecting the substrate and the transparent groove, and sealing an opening of the transparent groove is sealed by the sealing adhesive layer to cover the quantum dot layer, the barrier film layer and the phosphor layer.

Preferably, step of providing a transparent groove includes dispensing a mixture of quantum dots and adhesives on a bottom of the transparent groove by a dispensing process to form the quantum dot layer.

Preferably, step of providing a transparent groove includes forming the barrier film layer on the quantum dot layer and on the side walls of the transparent groove by an evaporation process or a magnetron sputtering process so that the side walls of the barrier film layer are connected and sealed with the side walls of the transparent groove.

Preferably, the barrier film layer is made of silicon oxide.

Preferably, one side of the phosphor layer is connected with the barrier film layer, and another side of the phosphor layer is connected with the sealing adhesive layer.

Preferably, the phosphor layer is formed by a dispensing process.

Preferably, the LED chip is a blue LED chip, the phosphor layer is a red phosphor layer, and the quantum dot layer is a green quantum dot layer.

Preferably, the transparent groove is made of glass.

In comparison with the prior art, the transparent groove is configured in the LED package device of the invention, and the quantum dot layer is provided inside the transparent groove, and the quantum dot layer is sealed because the side walls of the barrier film layer are connected and sealed with side walls of the transparent groove. In such a configuration, water vapor and oxygen are isolated from the quantum dot layer, thereby effectively avoiding the failure problem of the quantum dot layer. Meanwhile, due to the phosphor layer, part of the light emitted by LED chip will be firstly absorbed by the phosphor layer to reduce the energy density of the light emitted by LED chip, and then the remaining part of the light emitted by the LED chip will enter the quantum dot layer, which reduces the possibility of failure of the quantum dot material under strong light emission.

### BRIEF DESCRIPTION OF THE DRAWINGS

The accompanying drawings facilitate an understanding of the various embodiments of this invention. In such drawings:

FIG. 1 is a schematic diagram of a film of quantum dot film in the prior art;

FIG. 2 shows a schematic diagram of a quantum dot film mounted on an LED device in the prior art;

FIG. 3 is a schematic diagram of a failed quantum dot film in the LED device in FIG. 2;

FIG. 4 is a schematic diagram of an LED package device according to an embodiment of the invention; and

FIG. 5 is a flowchart of a packaging method of an LED package device according to an embodiment of the invention.

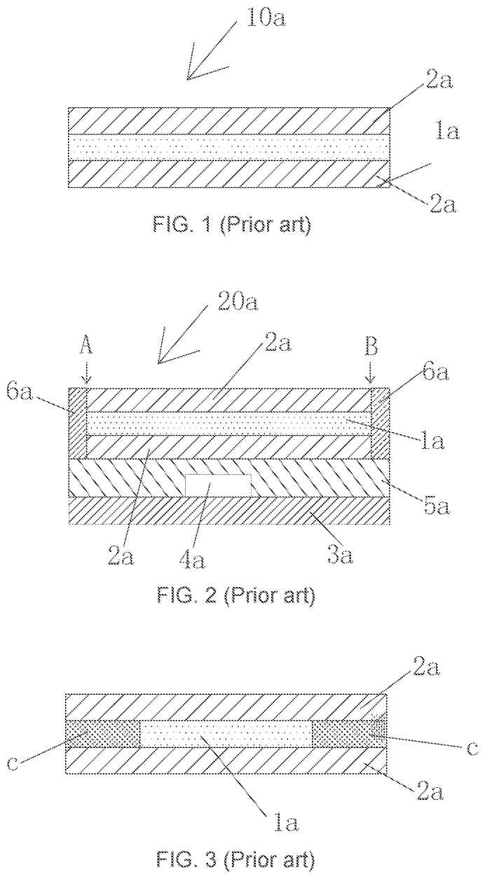

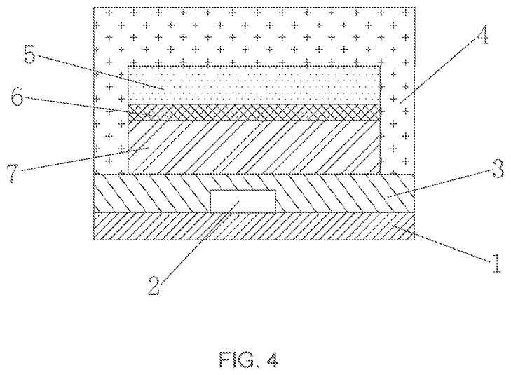

### DETAILED DESCRIPTION OF ILLUSTRATED EMBODIMENTS

In order to make the purpose, technical solutions and advantages of the present application more clearly understood, the present application will be described in further detail below with reference to the accompanying drawings and embodiments.

Referring to FIG. 4, an LED package device according to an embodiment of the present invention includes a substrate 1 and an LED chip 2 arranged on the substrate 1. The substrate 1 is provided with a sealing adhesive layer 3 for cladding the LED chip 2. The LED package device further includes a transparent groove 4, a quantum dot layer 5 is provided inside the transparent groove 4, a barrier film layer 6 is provided on the quantum dot layer 5, side walls of the barrier film layer 6 are connected and sealed with side walls of the transparent groove 4, and a phosphor layer 7 is further provided on the barrier film layer 6. The transparent groove 4 is inverted on the sealing adhesive layer 3 and connected with the sealing adhesive layer 3, and an opening of the transparent groove 4 is sealed by the sealing adhesive layer 3 to cover the quantum dot layer 5, the barrier film layer 6 and the phosphor layer 7.

Specifically, the transparent groove 4 is an integrated structure made of glass material, and the transparent groove 4 has an upper opening. Water vapor and oxygen may not enter the transparent groove 4 from other parts of the transparent groove 4, The quantum dot layer 5 is arranged at the bottom of the transparent groove 4, the barrier film layer 6 is arranged on the quantum dot layer 5, and the side walls of the barrier film layer 6 and the side walls of the transparent groove 4 are sealed and fixedly connected, in such a configuration, the quantum dot layer 5 is sealed in the space formed by the transparent groove 4 and the barrier film layer 6, which can effectively isolate water vapor and oxygen and avoid the failure of the quantum dot material in the quantum dot layer 5.

In the present embodiment, the transparent groove is configured, and the quantum dot layer 5 is provided inside the transparent groove 4, and the quantum dot layer 5 is sealed because the side walls of the barrier film layer 6 are connected and sealed with side walls of the transparent groove 4. In such a configuration, water vapor and oxygen are isolated from the quantum dot layer 5, thereby effectively avoiding the failure problem of the quantum dot layer. Meanwhile, due to the phosphor layer 7, part of the light emitted by LED chip 2 will be firstly absorbed by the phosphor layer 7 to reduce the energy density of the light emitted by LED chip 2, and then the remaining part of the light emitted by LED chip 2 will enter the quantum dot layer 5, which reduces the possibility of failure of the quantum dot material under strong light emission.

In the embodiment of the invention, as shown in FIG. 4, one side of the phosphor layer 7 is connected with the barrier film layer 6, and the other side of the phosphor layer 7 is connected with the sealing adhesive layer 3. By setting the phosphor layer 7 between barrier film layer 6 and sealing adhesive layer 3, not only the problem of uneven luminescence of LED chip 2 is solved, but also the distance between LED chip 2 and quantum dot layer 5 is increased, thereby preventing too high energy of the LED chip 2 which may result in the failure of quantum dot material in quantum dot layer 5.

Specifically, the phosphor layer 7 is a red phosphor layer, the barrier film layer 6 is made of silicon oxide material, the LED chip 2 is a blue LED chip, and the quantum dot layer 5 is a green quantum dot layer. The transparent groove 4 is bonded together with the LED chip 2 and the substrate 1 through the sealing adhesive layer 3, to form a white LED package device. The blue light emitted by LED chip 2 in the LED package device of the present invention first enters the red phosphor layer, and part of the blue light is absorbed by the red phosphor in the red phosphor layer and converted into red light, so that the energy density of blue light is attenuated. Secondly, the red phosphor particles are beneficial to the light diffusion to uniform the blue light distribution. The blue light with energy attenuation and uniform diffusion then enters the quantum dot layer 5 through the barrier film layer 6, and part of the blue light is absorbed and converted into green light by the quantum dot material in the quantum dot layer 5. Optionally, the thickness of the red phosphor layer 7 and the particles of the red phosphor may be adjusted according to actual needs. In this embodiment, one-third of the blue light may be absorbed by the red phosphor layer and converted into red light. The concentration of quantum dot material in the green quantum dot layer is also adjustable. In this embodiment, one-third of the blue light may be absorbed by the green light quantum dot layer and converted into green light. Thus, the red light produced by the red light phosphor, the green light produced by the quantum dot material and the remaining one-third of blue light are mixed together to produce white light, thereby forming the white LED package device. Due to the phosphor layer 7, part of the light emitted by LED chip 2 is firstly absorbed to reduce the energy density of the light emitted by LED chip 2, and then the remaining part of the blue light enters the quantum dot layer 5, which reduces the possibility of failure of the quantum dot material under strong light emission.

In the embodiment of the invention, the phosphor layer 7 with other colors such as orange may be applied. The quantum dot layer 5 may include quantum dot material with other colors. The luminous color of the LED chip 2 is not limited, which may be adjusted according to the actual needs.

In the LED package device of the invention embodiment, as shown in FIG. 4, a diffusion layer may be configured between the barrier film layer 6 and the phosphor layer 7 to further increase the uniformity of light emitted by LED chip 2. Optionally, other functional layers may be further added between the barrier film layer 6 and the phosphor layer 7 or between the phosphor layer 7 and the sealing adhesive layer 3, which is not limited here.

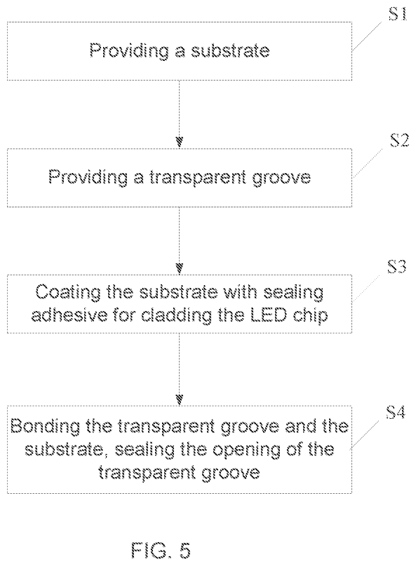

Referring to FIG. 4 and FIG. 5, the embodiment of the invention further provides a packaging method of an LED package device, including the following steps:
S1, providing a substrate 1 on which an LED chip 2 is provided;
S2, providing a transparent groove 4, wherein a quantum dot layer 5 is provided inside the transparent groove 4, a barrier film layer 6 is provided on the quantum dot layer 5, side walls of the barrier film layer 6 is connected and sealed with side walls of the transparent groove 4, and a phosphor layer 7 is further provided on the barrier film layer 6;
S3, coating the substrate 1 with sealing adhesive for cladding the LED chip 2; and
S4, inverting the transparent groove 4 on the sealing adhesive, solidifying the sealing adhesive to form a sealing adhesive layer 3 connecting the substrate 1 and the transparent groove 4, and sealing an opening of the transparent groove 4 is sealed by the sealing adhesive layer 3 to cover the quantum dot layer 5, the barrier film layer 6 and the phosphor layer 7.

In the packaging method of the present embodiment, the transparent groove is configured, and the quantum dot layer 5 is provided inside the transparent groove 4, and the quantum dot layer 5 is sealed because the side walls of the barrier film layer 6 are connected and sealed with side walls of the transparent groove 4. In such a configuration, water vapor and oxygen are isolated from the quantum dot layer 5, thereby effectively avoiding the failure problem of the quantum dot layer. Meanwhile, due to the phosphor layer 7, part of the light emitted by LED chip 2 will be firstly absorbed by the phosphor layer 7 to reduce the energy density of the light emitted by LED chip 2, and then the remaining part of the light emitted by LED will enter the quantum dot layer 5, which reduces the possibility of failure of the quantum dot material under strong light emission.

Referring to FIG. 4 and FIG. 5, in the step S2, the method further includes the following steps.

Dispensing a mixture of quantum dots and adhesives on a bottom of the transparent groove 4 by a dispensing process to form the quantum dot layer. Specifically, after the mixture of the quantum dot material and the adhesives is laid on the bottom of the transparent groove 4, and the mixture is dried and cured to form the quantum dot layer 5. The peripheral wall of the quantum dot layer 5 is connected with the inner wall of the transparent groove 4.

Forming the barrier film layer 6 on the quantum dot layer 5 and on the side walls of the transparent groove 4 by an evaporation process or a magnetron sputtering process so that the side walls of the barrier film layer 6 are connected and sealed with the side walls of the transparent groove 4. Specifically, the barrier film layer 6 is arranged on the upper surface of the quantum dot layer 5, and the barrier film layer 6 is made of silicon oxide. The barrier film layer 6 is formed by the evaporation process or magnetron sputtering process, which forms a sealed fixed connection with the side wall of the transparent groove 4, thereby effectively isolating water vapor and oxygen, and avoiding the failure of the quantum dot layer 5.

In the embodiment, as shown in FIG. 4, one side of the phosphor layer 7 is connected with the barrier film layer 6, and another side of the phosphor layer 7 is connected with the sealing adhesive layer 3.

Specifically, the phosphor layer 7 is formed by dispensing. By setting the phosphor layer 7 between barrier film layer 6 and sealing adhesive layer 3, not only the problem of uneven luminescence of LED chip 2 is solved, but also the distance between LED chip 2 and quantum dot layer 5 is increased, thereby avoiding too high energy of the LED chip 2 which may result in the failure of quantum dot material in quantum dot layer 5.

In the embodiments, the LED chip 2 is a blue LED chip, the phosphor layer 7 is a red phosphor layer, and the quantum dot layer 5 is a green quantum dot layer. The transparent groove 4 is bonded together with the LED chip 2 and the substrate 1 through the sealing adhesive layer 3, to form a white LED package device. Additionally, due to the existence of the phosphor layer 7, part of the blue light emitted by LED chip 2 is first absorbed by the phosphor layer 7 to reduce the energy density of the light emitted by LED chip 2, and then the remaining part of the blue light enters the quantum dot layer 5, which reduces the possibility of failure of the quantum dot material under strong light emission.

In the embodiment of the invention, the material of transparent groove 4 is glass. Specifically, a mask corresponding to the transparent groove 4 is firstly prepared and then covered on the surface of a piece of glass, and then the groove is made by chemical corrosion. The transparent groove 4 may be made of other transparent materials, as long as it may ensure the sealing and may form a barrier film layer on the side wall through the evaporation process or magnetron sputtering process.

In the embodiment of the invention, the side walls of the transparent groove 4 and the barrier film layer 6 on the surface of the quantum dot layer 5 form a closed cavity that is hermetically sealed, in which the quantum dot material is configured. The glass is an excellent material for water vapor and oxygen barrier, thus the cavity formed by the transparent groove 4 of glass material and the barrier film layer 6 is beneficial to protect the quantum dot material from the intrusion of water vapor and oxygen, which avoids the failure sides in the conventional “sandwich” structure.

In comparison with the prior art, since the barrier film layer 6 and the phosphor layer 7 are configured between quantum dot layer 5 and the LED chip 2, the quantum dot material in quantum dot layer 5 does not directly contact with LED chip 2, nor directly receive high energy density blue light emitted by LED chip 2, thereby effectively avoiding the failure problem of the quantum dot material. While the phosphor layer 7 may directly contact with the LED chip 2 and receive the blue light directly emitted by LED chip 2, and further it is not sensitive to water vapor and oxygen. Therefore, ordinary sealing adhesive, such as epoxy resin or silicone may be used as the sealing adhesive layer 3 to protect the phosphor layer 7.

The above-mentioned embodiments only denote several embodiments of the present application, and the descriptions thereof are relatively specific and detailed, but should not be construed as limiting the scope of the patent application. It should be pointed out that for those skilled in the art, several modifications and improvements can be made without departing from the concept of the present application, which all belong to the protection scope of the present application. Therefore, the scope of protection of the patent of the present application shall be subject to the appended claims.

What is claimed is:

1. An LED package device, comprising a substrate, an LED chip arranged on the substrate and a transparent groove, the substrate being provided with a sealing adhesive layer for cladding the LED chip;
wherein a quantum dot layer is provided inside the transparent groove, a barrier film layer is provided on the quantum dot layer, side walls of the barrier film layer are connected and sealed with side walls of the transparent groove, and a phosphor layer is further provided on the barrier film layer;
the transparent groove is inverted on the sealing adhesive layer and connected with the sealing adhesive layer, and an opening of the transparent groove is sealed by the sealing adhesive layer to cover the quantum dot layer, the barrier film layer and the phosphor layer.

2. The LED package device according to claim 1, wherein one side of the phosphor layer is connected with the barrier film layer, and another side of the phosphor layer is connected with the sealing adhesive layer.

3. A packaging method of an LED package device, comprising:
providing a substrate on which an LED chip is provided;
providing a transparent groove, wherein a quantum dot layer is provided inside the transparent groove, a barrier film layer is provided on the quantum dot layer, side walls of the barrier film layer are connected and sealed with side walls of the transparent groove, and a phosphor layer is further provided on the barrier film layer;
coating the substrate with sealing adhesive for cladding the LED chip; and
inverting the transparent groove on the sealing adhesive, solidifying the sealing adhesive to form a sealing adhesive layer connecting the substrate and the transparent groove, and sealing an opening of the transparent groove is sealed by the sealing adhesive layer to cover the quantum dot layer, the barrier film layer and the phosphor layer.

4. The packaging method according to claim 3, wherein said providing a transparent groove comprises:
dispensing a mixture of quantum dots and adhesives on a bottom of the transparent groove by a dispensing process to form the quantum dot layer.

5. The packaging method according to claim 3, wherein said providing a transparent groove further comprises:
forming the barrier film layer on the quantum dot layer and on the side walls of the transparent groove by an evaporation process or a magnetron sputtering process so that the side walls of the barrier film layer are connected and sealed with the side walls of the transparent groove.

6. The packaging method according to claim 3, wherein the barrier film layer is made of silicon oxide.

7. The packaging method according to claim 3, wherein one side of the phosphor layer is connected with the barrier film layer, and another side of the phosphor layer is connected with the sealing adhesive layer.

8. The packaging method according to claim 7, wherein the phosphor layer is formed by a dispensing process.

9. The packaging method according to claim 5, wherein the LED chip is a blue LED chip, the phosphor layer is a red phosphor layer, and the quantum dot layer is a green quantum dot layer.

10. The packaging method according to claim 5, wherein the transparent groove is made of glass.
